(19) United States
(12) Patent Application Publication
(10) Pub. No.: US 2026/0353830 A1
(43) Pub. Date: Nov. 5, 2026

(54) IMAGE SENSING DEVICE AND METHOD OF MANUFACTURING THE SAME

(71) Applicant: SK hynix Inc., Icheon-si (KR)

(72) Inventor: Yun Hui YANG, Icheon-si (KR)

(21) Appl. No.: 19/309,932

(22) Filed: Aug. 26, 2025

(30) Foreign Application Priority Data
Apr. 30, 2025 (KR) 10-2025-0057344

(51) Int. Cl. H10F 39/00; H10F 39/18

(52) U.S. Cl. CPC H10F 39/8057; H10F 39/014; H10F 39/182; H10F 39/8067

(57) ABSTRACT

Image sensing devices and manufacturing methods are disclosed. In an embodiment, an image sensing device may include a plurality of insulating layers that includes a first insulating layer, a second insulating layer disposed over the first insulating layer, and a third insulating layer disposed over the reflective pattern; a substrate portion disposed over the third insulating layer; a photodetector disposed within the substrate portion and configured to convert incident light into an electrical signal; a reflective pattern disposed between the second insulating layer and the third insulating layer and configured to reflect light toward the photodetector; and an isolation layer disposed between the substrate portion and an adjacent substrate portion, wherein the reflective pattern is in direct contact with the isolation layer.

### CROSS REFERENCE TO RELATED APPLICATION

This patent document claims the priority and benefits of Korean Patent Application No. 10-2025-0057344, filed on Apr. 30, 2025, the disclosure of which is incorporated herein by reference in its entirety.

### TECHNICAL FIELD

Embodiments of the disclosed technology relate to an image sensing device and a method of manufacturing the same.

### BACKGROUND

With the development of information and communication technologies and the digitalization of electronic devices, high-performance image sensors are increasingly being used in various applications, such as digital cameras, camcorders, mobile phones, personal communication systems (PCS), game devices, security cameras, and medical micro cameras.

In general, an image sensor includes a pixel area that includes a photodetector such as a photodiode, and a peripheral circuit area. A unit pixel includes a photodiode and a transistor. The transistor is placed between the photodiode and a floating diffusion region to transfer charges generated by the photodiode to the floating diffusion region.

### SUMMARY

Embodiments of the disclosed technology provide an image sensing device that may reduce light incident loss and improve light reflection efficiency. Embodiments of the disclosed technology also provide a method of manufacturing the image sensing device.

Embodiments of the disclosed technology provide an image sensing device that may enable smoother collection of incident light. Embodiments of the disclosed technology also provide a method of manufacturing the image sensing device.

Embodiments of the disclosed technology provide an image sensing device with reduced cross-talk between adjacent pixels. Embodiments of the disclosed technology also provide a method of manufacturing the image sensing device.

Embodiments of the disclosed technology provide an image sensing device that may improve detection performance of an image sensor, thereby improving signal quality and enhancing image quality. Embodiments of the disclosed technology also provide a method of manufacturing the image sensing device.

The technical effects and advantages of the disclosed technology are not limited to those mentioned above, and additional benefits may become apparent from the following embodiments.

In an embodiments of the disclosed technology, an image sensing device based on an embodiment may include a plurality of insulating layers including a first insulating layer, a second insulating layer disposed over the first insulating layer, and a third insulating layer disposed over the reflective pattern; a substrate portion disposed over the third insulating layer; a photodetector disposed within the substrate portion and configured to convert incident light into an electrical signal; a reflective pattern disposed between the second insulating layer and the third insulating layer and configured to reflect light toward the photodetector; and an isolation layer disposed between the substrate portion and an adjacent substrate portion, wherein the reflective pattern may be in direct contact with the isolation layer.

An image sensing device based on another embodiment of the disclosed technology may include a substrate portion; a photodetector disposed within the substrate portion and configured to convert incident light into an electrical signal; an isolation layer disposed adjacent to the substrate portion; and a reflective pattern disposed below the substrate portion and configured to reflect light toward the photodetector, wherein the substrate portion is disposed in a pixel area, and the isolation layer is disposed in a non-pixel area disposed adjacent to the pixel area, wherein the reflective pattern encloses the pixel area.

A method of manufacturing an image sensing device based on an embodiment of the disclosed technology may include forming an isolation layer by recessing a substrate portion including a photodetector in a thickness direction the substrate portion; patterning a third insulating layer disposed over the substrate portion; patterning a reflective pattern disposed over the third insulating layer; and patterning a second insulating layer disposed over the reflective pattern, wherein the reflective pattern may be in direct contact with an isolation layer disposed between the substrate portion and an adjacent substrate portion.

In some embodiments, the image sensing device and the method of manufacturing the image sensing device may reduce the loss of light incident and reflect the light more efficiently.

Furthermore, the image sensing device and the method of manufacturing the image sensing device may enhance light collection, leading to improved overall optical performance.

In addition, cross-talk between adjacent pixels may be reduced.

As a result, the detection performance of the image sensor may be improved, thereby improving signal quality and overall image quality.

However, it should be understood that the detailed description and specific examples are provided for illustration only. Various modifications and changes may be made based on the specific examples.

### BRIEF DESCRIPTION OF THE DRAWINGS

FIG. 1 is a block diagram showing an image sensing device based on an embodiment.

FIG. 2 is an enlarged plane view of a pixel array based on an embodiment.

FIG. 3 is a cross-sectional view taken along A-A’ of FIG. 2.

FIGS. 4-9 are views showing processes included in a method of manufacturing the image sensing device based on an embodiment.

FIG. 10 is a cross-sectional view of an image sensing device based on another embodiment.

FIG. 11 is a cross-sectional view of an image sensing device based on another embodiment.

FIG. 12 is a cross-sectional view of an image sensing device based on another embodiment.

FIG. 13 is a cross-sectional view of an image sensing device based on another embodiment.

FIG. 14 is a cross-sectional view of an image sensing device based on another embodiment.

FIG. 15 is a cross-sectional view of an image sensing device based on another embodiment.

### DETAILED DESCRIPTION

The following description provides detailed explanation of example embodiments with reference to the accompanying drawings.

It should be understood that terms such as “first” and “second” are used herein to distinguish between different components and do not imply any particular order or hierarchy. For example, a “first” component may be referred to as a “second” component and vice versa. Additionally, singular forms may include the plural unless the context clearly indicates otherwise.

Terms such as "below," "underneath," "above," and "on" are used to describe the relative positions of components shown in the drawings. These terms are used for convenience of explanation based on the orientation shown in the drawings.

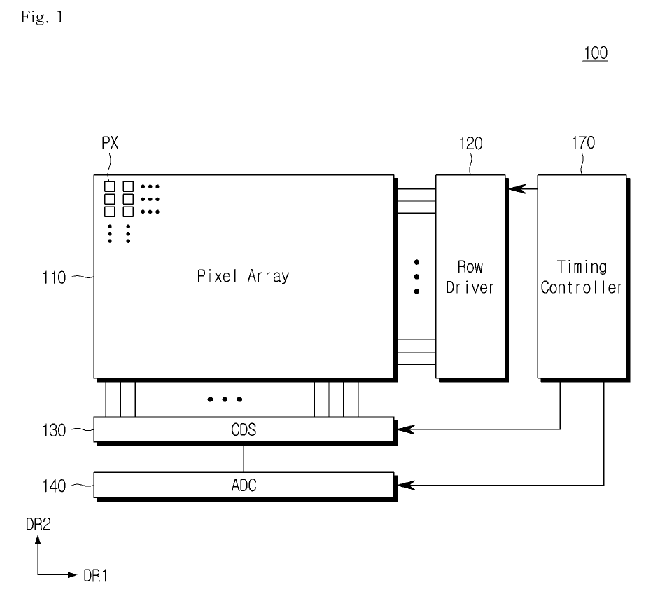

FIG. 1 is a block diagram showing an image sensing device based on an embodiment.

Referring to FIG. 1, the image sensing device 100 may be a complementary metal oxide semiconductor image sensor (CIS) that converts an optical image into an electrical signal. The overall operation of the image sensing device 100, such as power control (e.g., power on/off), operation mode, operation timing, and sensitivity, may be managed by a control circuit.

The image sensing device 100 may include a pixel array 110, a row driver 120, a correlated double sampler CDS 130, an analog-to-digital converter ADC 140, and a timing controller 170. These components of the image sensing device 100 are provided by way of example only, and additional components may be included or certain components may be omitted depending on implementation needs.

The pixel array 110 may include a plurality of image pixels arranged in rows and columns to form a two-dimensional array. For example, the pixels may be arranged repeatedly in a second direction (DR2). Each image pixel may convert incident light into an electrical signal, either individually or as part of a pixel group.

Each image pixel can detect incident light by generating a photocharge corresponding to the intensity (or illuminance) of incident light and generating an electrical signal based on the amount of generated photocharge. For convenience of explanation, the image pixel may also be referred to as a” pixel.”

The pixel array 110 may include a plurality of pixels PX. The pixels PX may be arranged in a matrix pattern along the row direction (or the first direction DR1) and the column direction (or the second direction DR2), but the disclosed technology is not limited thereto. The pixels PX may include a red pixel, a green pixel, and a blue pixel, but the disclosed technology is not limited thereto, and may further include a white pixel or an infrared pixel.

The plurality of pixels PX may be electrically connected to the row driver 120.

The row driver 120 may activate the pixel array 110 to perform specific operations on the pixels included in a specific row based on commands and control signals supplied by the timing controller 170.

In one embodiment, the correlated double sampler 130 may sequentially sample and hold a reference signal and an image signal provided to each of a plurality of column lines from the pixel array 110.

The correlated double sampler 130 may transmit the reference signal and the image signal of each column as a correlated double sampling signal to the ADC 140 based on the control signal from the timing controller 170.

The ADC 140 may convert the correlated double sampling signal for each column output from the correlated double sampler 130 into a digital signal and output image data. In one embodiment, the ADC 140 may convert the correlated double sampling signal generated by the correlated double sampler 130 for each column into a digital signal.

The ADC 140 may include a plurality of column counters corresponding to each column of the pixel array 110. Each column of the pixel array 110 is connected to each column counter, and the image data may be generated by converting the correlated double sampling signal corresponding to each column into a digital signal using the column counters.

Although not shown, the image sensing device 100 may further include an output buffer and a column driver.

The output buffer may temporarily hold and output image data of each column unit provided from the ADC 140. The output buffer may temporarily store image data output from the ADC 140 based on a control signal of the timing controller 170.

The column driver may select a column of the output buffer based on the control signal of the timing controller 170 and control the output buffer so that image data temporarily stored in the selected column of the output buffer is sequentially output.

The timing controller 170 may control at least one of the row driver 120, the correlated dual sampler 130, the ADC 140, the output buffer, or the column driver.

The timing controller 170 may provide a clock signal required for the operation of each component of the image sensing device 100, a control signal for timing control, and address signals for selecting a row or column.

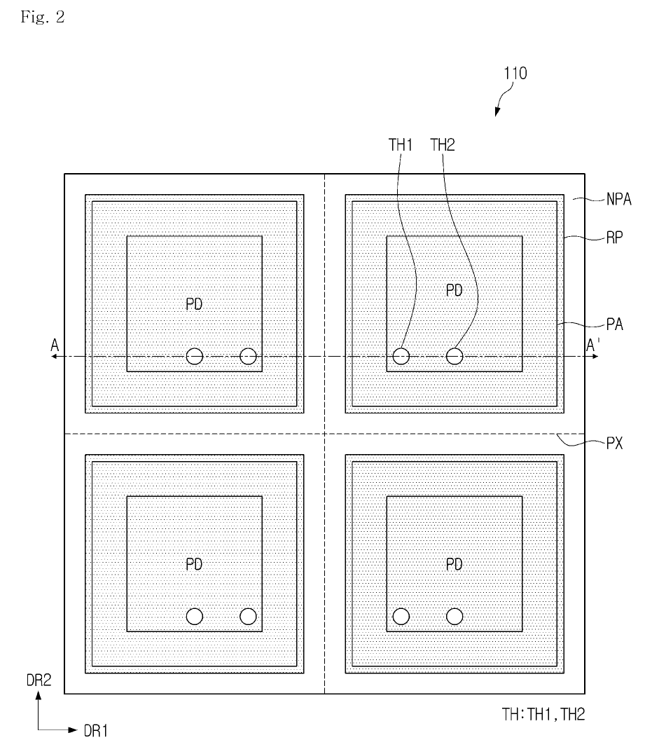

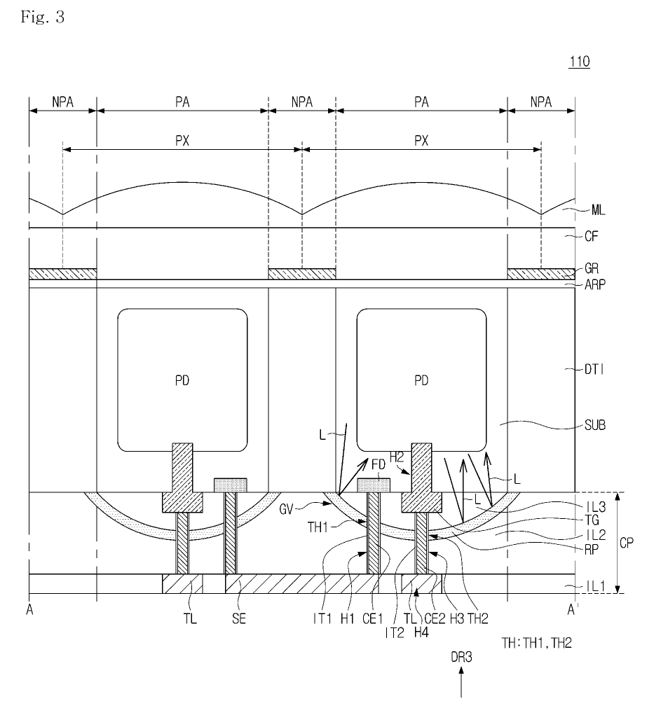

FIG. 2 is an enlarged plane view of a pixel array based on an embodiment. FIG. 3 is a cross-sectional view taken along A-A’ of FIG. 2. FIG. 3 also shows the path of external light incident on the pixel array.

Referring to FIGS. 2 and 3, the pixel array 110 may include a plurality of pixels PX. Each pixel PX may include a pixel area PA and a non-pixel area NPA that is disposed adjacent to the pixel area PA. The non-pixel area NPA may be arranged to partially or entirely surround the pixel area PA, but the disclosed technology is not limited thereto.

The pixel area PA may convert incident light into an electrical signal. A photodetector PD may be arranged in each pixel area PA. Each pixel area PA may convert incident light into an electrical signal through the photodetector PD.

For example, the photodetector PD may be implemented as a photodiode, a phototransistor, a photogate, a pinned photodiode, or a combination thereof. When the photodetector PD is implemented as a photodiode, it may be a region doped with an impurity of a second conductivity type (e.g., N-type) within a substrate portion having a first conductivity type (e.g., P-type).

The non-pixel region NPA may not receive the incident light, or may not convert the received incident light into an electrical signal. The non-pixel region NPA may be arranged between each pixel region PA and may distinguish a plurality of pixels PX and a plurality of pixel regions PA.

The pixel array 110 may include a circuit portion CP, a substrate portion SUB on the circuit portion CP, an anti-reflection layer ARP on the substrate portion SUB, a grid portion GR on the anti-reflection layer ARP, a color filter CF on the grid portion GR, and a micro lens ML on the color filter CF.

The circuit portion CP is arranged on the lower surface of the substrate portion SUB and may include transistors, a wiring layer (e.g., interconnect), an interlayer insulating layer, and a reflective pattern RP. The circuit portion CP may include electrodes, wiring, and connecting portions arranged within a first insulating layer IL1, a second insulating layer IL2, a third insulating layer IL3, and grooves H1, H2, H3, and H4 formed in each of the insulating layers IL1, IL2, and IL3.

The first insulating layer IL1 may include a plurality of fourth grooves H4. The fourth groove H4 may completely penetrate from the lower surface to the upper surface of the first insulating layer IL1. For example, a transmission control line TL and a shared electrode SE may be arranged in each of the fourth grooves H4. Although not shown, a reset source line, a transmission control line, and a similar signal line may be further arranged in the fourth grooves H4.

The second insulating layer IL2 may be arranged on the first insulating layer IL1. The second insulating layer IL2 may define a reflection groove GV that is partially recessed from the upper surface toward the lower surface. Here, the upper surface of the second insulating layer IL2 is a surface facing the substrate portion SUB, and the lower surface can refer to a surface facing the first insulating layer IL1.

The reflective pattern RP may be arranged on the second insulating layer IL2. The reflective pattern RP may be arranged within the reflection groove GV. The reflective pattern RP may be formed of a material having high light reflectivity. For example, the reflective pattern RP may include a metal material. The metal material may include tungsten W, aluminum Al, or one or more other metal materials, or combinations thereof.

The reflective pattern RP may be formed match the shape of the reflection groove GV. For example, the reflective pattern RP may be formed in a dome shape. The reflective pattern RP may have a convex shape extending from the substrate portion SUB toward the first insulation layer IL1. However, the disclosed technology is not limited to these examples.

The reflective pattern RP may be arranged between the second insulation layer IL2 and the third insulation layer IL3. The reflective pattern RP may have a lower surface in direct contact with the second insulating layer IL2 and an upper surface in direct contact with the third insulating layer IL3. The second insulating layer IL2 and the third insulating layer IL3 may be separated and spaced apart from each other by the reflective pattern RP.

In some embodiments, the reflective pattern RP may be formed for each pixel PX and may be spaced apart from neighboring reflective patterns. However, the disclosed technology is not limited thereto. In some embodiments, at least some of the reflective patterns RP arranged for each pixel PX may be connected to each other, or the entire reflective pattern RP may be formed as one piece.

The reflective pattern RP may be arranged in the pixel area PA. The reflective pattern RP may cover the entire area of the pixel area PA. The reflective pattern RP may overlap the entire area of the pixel area PA in the thickness direction (the third direction DR3).

The reflective pattern RP may cover the entire area of the photodetector PD. The reflective pattern RP may overlap the entire area of the photodetector PD in the thickness direction (third direction DR3).

The reflective pattern RP may extend from the pixel area PA and may also be arranged in a portion of the non-pixel area NPA. The reflective pattern (RP) may cover a portion of the non-pixel area NPA. The reflective pattern RP may overlap a portion of the non-pixel area NPA in the thickness direction (the third direction DR3).

The reflective pattern RP may be in direct contact with the isolation layer DTI. Here, the reflective pattern RP being in direct contact with the isolation layer DTI may refer to the reflective pattern RP in direct contact with the isolation layer DTI defined by the substrate portion SUB or the reflective pattern RP in direct contact with a material filling the isolation layer DTI.

The reflective pattern RP may be in direct contact with the lower surface of the isolation layer DTI. Here, the lower surface of the isolation layer DTI may refer to a surface facing the second insulating layer IL2. However, the disclosed technology is not limited thereto, and the reflective pattern RP may directly contact the side of the isolation layer DTI.

In other words, the reflective pattern RP and the isolation layer DTI may be in direct contact with each other at the bottom of the substrate portion SUB. As a result, there may be little to no space at the bottom of the substrate portion SUB through which light incident on the pixel array 110 can leak.

Since the reflective pattern RP is arranged to directly contact the isolation layer DTI, light leakage into adjacent pixels PX at the bottom of the substrate portion SUB may be suppressed. As a result, optical cross-talk between adjacent pixels PX may be reduced.

In some embodiments, the reflective pattern RP is configured to reflect incident light toward the photodetector PD. As illustrated in FIG. 3, light (L) incident on the pixel array 110 may be reflected by the reflective pattern RP and directed back toward the photodetector PD. Since the reflective pattern RP is arranged to be in direct contact with the isolation layer DTI, light leakage into adjacent pixels PX disposed under the isolation layer DTI may be suppressed, thereby reducing overall light loss. Therefore, light (L) incident on the pixel array 110 may be more effectively reflected and collected by the reflective pattern RP.

Furthermore, the detection performance of the image sensing device (100, see FIG. 1) may be improved, resulting in improved signal quality and overall image quality.

The reflective pattern RP may include at least one through hole (TH: TH1 and TH2). These through holes TH may allow electrical connection between components arranged on the upper and lower sides of the reflective pattern RP.

Since the reflective pattern RP includes the through hole TH, a connecting portion (e.g., CE1 and CE2) may be arranged within the through hole TH. Accordingly, even if the reflective pattern RP directly contacts the isolation layer DTI and covers the entire area of the pixel area PA, the components arranged on the upper and lower sides of the reflective pattern RP may be electrically connected.

The first through hole TH1 may form part of the first groove H1, and the second through hole TH2 may form part of the third groove H3.

In FIGS. 2 and 3, only the first through hole TH1 and the second through hole TH2 are shown, but the disclosed technology is not limited thereto. For example, the reflective pattern RP may include three or more through holes TH depending on the design of the circuit portion CP.

The third insulating layer IL3 may be arranged on the reflective pattern RP. When the reflective pattern RP has a dome shape, the third insulating layer IL3 may be arranged within the reflective pattern RP. The third insulating layer IL3 may be arranged between the reflective pattern RP and the substrate portion SUB. The third insulating layer IL3 may be surrounded by the reflective pattern RP and the substrate portion SUB, but the disclosed technology is not limited thereto.

The third insulating layer IL3 may cover the entire area of the pixel area PA, but the disclosed technology is not limited thereto. The third insulating layer IL3 may have the same planar size (or area) as the pixel area PA, but the disclosed technology is not limited thereto. The border of the third insulating layer IL3 may be aligned with the border of the pixel area PA, but the disclosed technology is not limited thereto.

The third insulating layer IL3 may be surrounded by the reflective pattern RP and the substrate portion SUB. The third insulating layer IL3 may be sealed by the reflective pattern RP and the substrate portion SUB.

The circuit portion CP may further include a first groove H1 and a third groove H3. The first groove H1 and the third groove H3 may completely penetrate the second insulating layer IL2, the reflective pattern RP, and the third insulating layer IL3 in the thickness direction (the third direction DR).

The first intermediate insulating layer IT1 and the first connecting portion CE1 may be arranged in the first groove H1. The first intermediate insulating layer IT1 may be arranged along the inner wall of the first groove H1. The first connecting portion CE1 may be arranged inside the first intermediate insulating layer IT1. The first connecting portion CE1 may be arranged to be surrounded by the first intermediate insulating layer IT1. The first connecting portion CE1 may be arranged between the first intermediate insulating layer IT1 and the second insulating layer IL2, between the first intermediate insulating layer IT1 and the reflective pattern RP, and between the first intermediate insulating layer IT1 and the third insulating layer IL3.

Even if the reflective pattern RP includes a metal material, the reflective pattern RP and the first connecting portion CE1 may be insulated by the first intermediate insulating layer IT1, thereby preventing a short circuit.

The first connecting portion CE1 may be arranged within the first groove H1. The first connecting portion CE1 may have one end in contact with the shared electrode SE and the other end in contact with the floating diffusion region FD. The first connecting portion CE1 may be connected between the shared electrode SE and the floating diffusion region FD through the first groove H1. By the first connecting portion CE1, the shared electrode SE and the floating diffusion region FD may be electrically connected.

The floating diffusion region FD may be arranged on the third insulating layer IL3. The floating diffusion region FD may be arranged within the substrate portion SUB. The floating diffusion region FD may receive and accumulate photocharges generated in the photodetector PD.

For example, the floating diffusion region FD may be a region doped with an impurity of a second conductive type (e.g., N-type) on the substrate portion SUB having a first conductive type (e.g., P-type), and the substrate portion SUB and the impurity doped region may be modeled as a junction capacitor.

The floating diffusion regions FD of adjacent pixels PX may be electrically connected and shared via a shared electrode SE. As illustrated in FIG. 3, the floating diffusion regions FD of two adjacent pixels PX are electrically connected to each other (e.g., two adjacent pixels PX may share a floating diffusion regions FD), but the disclosed technology is not limited thereto. For example, the floating diffusion regions FD of three or more pixels PX may be electrically connected to each other (e.g., two adjacent pixels PX may share a floating diffusion regions FD).

A second intermediate insulating layer IT2 and a second connection portion CE2 may be arranged in the third groove H3. The second intermediate insulating layer IT2 may be arranged along the inner wall of the third groove H3. The second connecting portion CE2 may be arranged inside the second intermediate insulating layer IT2. The second connecting portion CE2 may be arranged, such that it is surrounded by the second intermediate insulating layer IT2. The second connecting portion CE2 may be arranged between the second intermediate insulating layer IT2 and the second insulating layer IL2, between the second intermediate insulating layer IT2 and the reflective pattern RP, and between the second intermediate insulating layer IT2 and the third insulating layer IL3.

Even if the reflective pattern RP includes a metal material, the reflective pattern RP and the second connecting portion CE2 may be insulated by the second intermediate insulating layer IT2, thereby preventing a short circuit.

The second connecting portion CE2 may be arranged within the third groove H3. The second connecting portion CE2 may have one end in contact with the transmission control line TL and the other end in contact with the gate electrode TG. The second connecting portion CE2 may be connected between the transmission control line TL and the gate electrode TG through the third groove H3. The transmission control line TL and the gate electrode TG may be electrically connected by the second connection portion CE2.

The gate electrode TG may further extend from the third insulating layer IL3 in the third direction DR3 and may directly contact the substrate portion SUB and the photodetector PD. The substrate portion SUB may define the second groove H2. The second groove H2 may be formed to penetrate the substrate portion SUB between the third insulating layer IL3 and the photodetector PD in the thickness direction (the third direction DR3). The gate electrode TG may contact the photodetector PD through the second groove H2.

The gate electrode TG may partially overlap with the photodetector PD. At least a portion of the gate electrode TG may be inserted into the photodetector PD. Accordingly, the transfer of photocharges generated from the photodetector PD may be facilitated.

The gate electrode TG may be the gate electrode of a transfer transistor arranged between the photodetector PD and the floating diffusion region FD , but the disclosed technology is not limited thereto. The transfer transistor may be turned on or off according to a transfer signal to transfer photocharges accumulated in the photodetector PD to the floating diffusion region FD.

In FIG. 3, the gate electrode TG of the transfer transistor and the floating diffusion region FD are shown, but the disclosed technology is not limited thereto. For example, a semiconductor region of the transfer transistor, a reset transistor, a driver transistor, a selection transistor, etc. may be further arranged.

The reset transistor is connected between a power supply voltage and the floating diffusion region FD, and may reset the voltage of the floating diffusion region FD to the power supply voltage in response to a pixel reset signal applied to the gate electrode.

The driver transistor is connected between the power supply voltage and the selection transistor, and can amplify the change in the electric potential of the floating diffusion region FD that has received the photocharge accumulated in the photodetector PD and transmit the amplified signal to the selection transistor.

The selection transistor is connected between the driver transistor and the output signal line (or column line), and may be turned on by a row selection signal applied to the gate electrode to output the electric signal transmitted from the driver transistor as a pixel signal.

When these configurations are further arranged, the reflective pattern RP may further include an additional through hole depending on the connection relationship of each configuration.

The substrate portion SUB may be disposed on the second insulating layer IL2, the third insulating layer IL3, and the connecting portion CE1 and CE2. The substrate portion SUB may include silicon (Si) and may have, for example, a first conductivity type (e.g., P type). The photodetector PD is disposed within the substrate portion SUB and may have the second conductivity type (e.g., N-type).

The isolation layer DTI may be disposed within the substrate portion SUB. The isolation layer DTI may be disposed in a non-pixel area NPA, and the isolation layer DTI may completely penetrate the substrate portion SUB, but the disclosed technology is not limited thereto. When the isolation layer DTI completely penetrates the substrate portion SUB, the isolation layer DTI may expose the circuit portion CP. For example, when the isolation layer DTI completely penetrates the substrate part SUB, the isolation layer DTI may expose the second insulating layer IL2.

The isolation layer DTI may be formed in a deep trench isolation manner. The isolation layer DTI may include an insulating material and/or a conductive material. The isolation layer DTI may be filled with an insulating material and/or a conductive material.

Examples of the insulating material may include hafnium oxide (HfOx), silicon oxide (SiOx), or tantalum oxide (TaOx), but the disclosed technology is not limited thereto. Examples of the conductive material may include polysilicon, but the disclosed technology is not limited thereto. For example, the isolation layer DTI may have a structure in which a conductive material is sandwiched between insulating materials, but the disclosed technology is not limited thereto.

An anti-reflection layer ARP may be disposed on the upper surface of the substrate portion SUB. The anti-reflection layer ARP may include at least one insulating material, for example, hafnium oxide (HfOx), silicon oxide (SiOx), or tantalum oxide (TaOx), but the disclosed technology is not limited thereto. The anti-reflection layer ARP may serve to prevent light passing through the color filter CF from being reflected and to allow light to be incident on the substrate portion SUB.

The grid portion GR may be arranged on the upper surface of the anti-reflection layer ARP. The grid portion GR may be arranged in the non-pixel area NPA. The grid portion GR may absorb or reflect light incident on the grid portion GR. The grid portion GR may prevent light mixing between adjacent pixel areas.

The grid portion GR may include a light absorbing material or a low-refractive layer. For example, when the grid portion GR includes a light absorbing material, it may include a metal material. The metal material may include tungsten (W), but the disclosed technology is not limited thereto. For example, when the grid portion GR includes a low-refractive layer, the grid portion GR may include a low-refractive insulating material or an air structure.

The color filter CF may be arranged on the anti-reflection layer ARP and the grid portion GR on the upper surface of the substrate portion SUB. The color filter CF may include a red color filter, a green color filter, or a blue color filter. In some embodiments, the color filter CF may further include a white color filter.

The micro lens ML may be arranged on the color filter CF. The micro lens ML may serve to receive light incident from the outside into the pixel area PA. To this end, the micro lens ML may have a shape of a convex lens that is convex upward, and may be formed of a material having a large difference in refractive index compared to the outside air (Air). For example, the refractive index of the micro lens ML may be about 1.5 to about 1.7, but the disclosed technology is not limited thereto.

Hereinafter, a method of manufacturing the image sensing device will be described. For components that are substantially the same as those described with reference to FIGS. 1-3, the same numeral references are used, and redundant descriptions may be omitted or simplified.

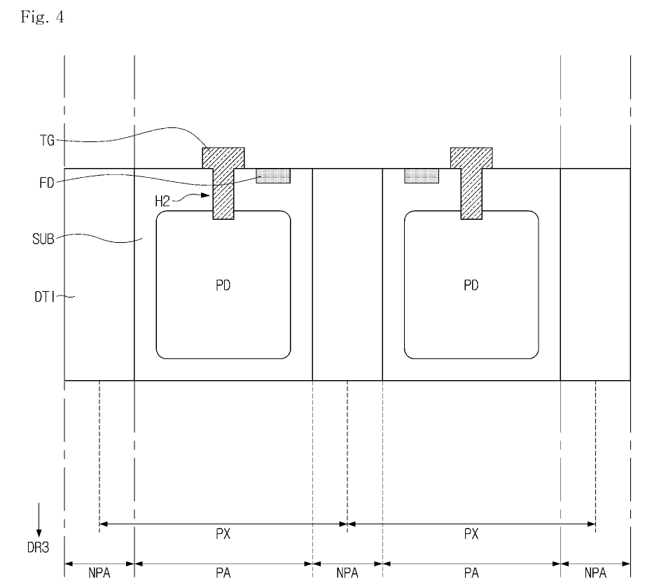

FIGS. 4-9 are views showing processes included in a method of manufacturing the image sensing device based on an embodiment.

First, referring to FIG. 4, the substrate portion SUB on which the isolation layer DTI is formed may be prepared. The isolation layer DTI may be formed by recessing the substrate portion SUB in the thickness direction (third direction DR3), but the disclosed technology is not limited thereto.

The photodetector PD may be arranged inside the substrate portion SUB. The gate electrode TG and the floating diffusion region FD may be arranged on one surface of the substrate portion SUB. Here, the one surface of the substrate portion SUB may refer to the lower surface of the substrate portion SUB of FIG. 3.

The second groove H2 may be formed between one surface of the substrate portion SUB and the photodetector PD. The second groove H2 may expose the photodetector PD. The gate electrode TG may contact the photodetector PD while filling the second groove H2. The floating diffusion region FD may be inserted into the substrate portion SUB and arranged on one side of the substrate portion SUB.

Next, the third insulating layer IL3 is patterned on one side of the substrate portion SUB. The third insulating layer IL3 may be arranged over the entire area of the substrate potion SUB and the isolation layer DTI, and then etched and patterned. The patterned third insulating layer IL3 may be arranged on the substrate portion SUB.

The third insulating layer IL3 may be formed into a dome shape through a patterning process. In order to form the third insulating layer IL3 in a dome shape, a photoresist having a dome shape can be formed on the third insulating layer IL3. The third insulating layer IL3 arranged over the entire area of the substrate portion SUB and the isolation layer DTI may be patterned using the photoresist, such that it remains only on the substrate portion SUB, and the third insulating layer IL3 arranged on the substrate portion SUB may be formed into a dome shape.

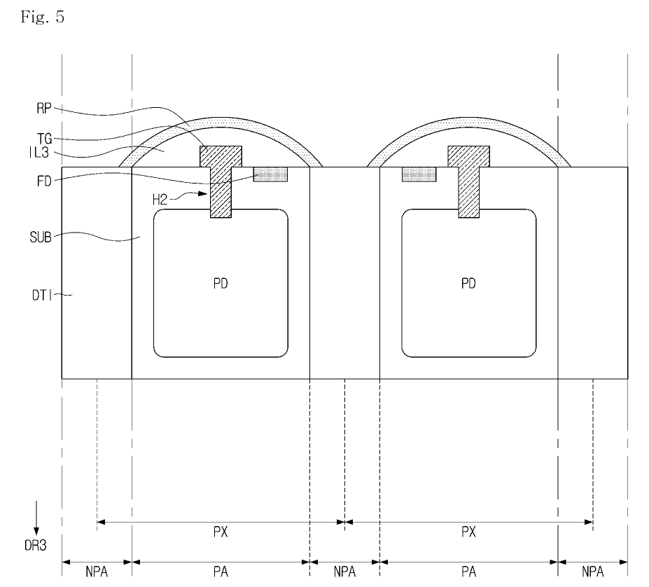

Next, referring to FIG. 5, the reflective pattern RP is formed on the third insulating layer IL3. The reflective pattern RP may be arranged over the entire area of the third insulating layer IL3 and the isolation layer DTI, and then patterned through etching. The patterned reflective pattern RP may remain only on the third insulating layer IL3. The reflective pattern RP may cover the entire area of the third insulating layer IL3.

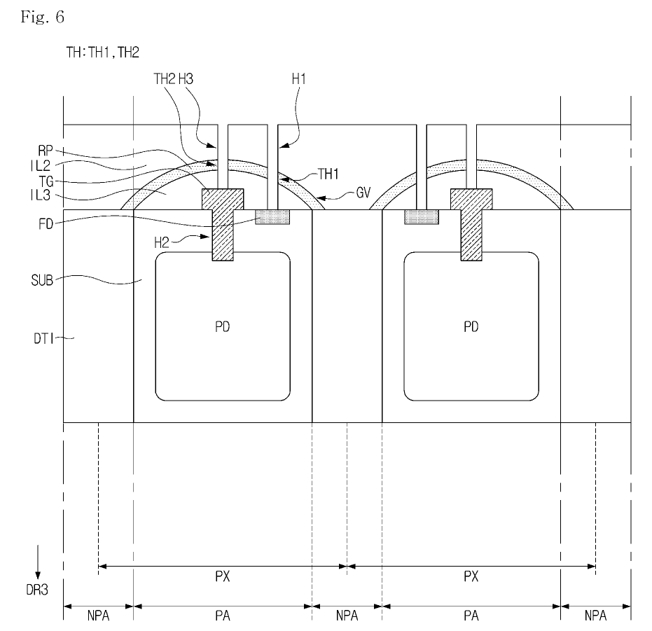

Next, referring to FIG. 6, the second insulation layer IL2 is formed on the reflective pattern RP, and the first groove H1 and the third groove H3 are formed.

The second insulation layer IL2 may be arranged on the isolation layer DTI and the substrate portion SUB while covering the reflective pattern RP. Thereafter, the first groove H1 and the third groove H3 may be formed through etching.

The first groove H1 may be formed by etching the second insulation layer IL2, the reflective pattern RP, and the third insulation layer IL3 by etching through the thickness direction (the third direction DR3). The first groove H1 may expose the gate electrode TG.

In the process of forming the first groove H1, the first through hole TH1 may be formed together.

The second insulating layer IL2, the reflective pattern RP, and the third insulating layer IL3 may be etched through the thickness direction (the third direction DR3) to form the third groove H3. The third groove H3 may expose the floating diffusion region FD.

In the process of forming the third groove H3, the second through hole TH2 may be formed together.

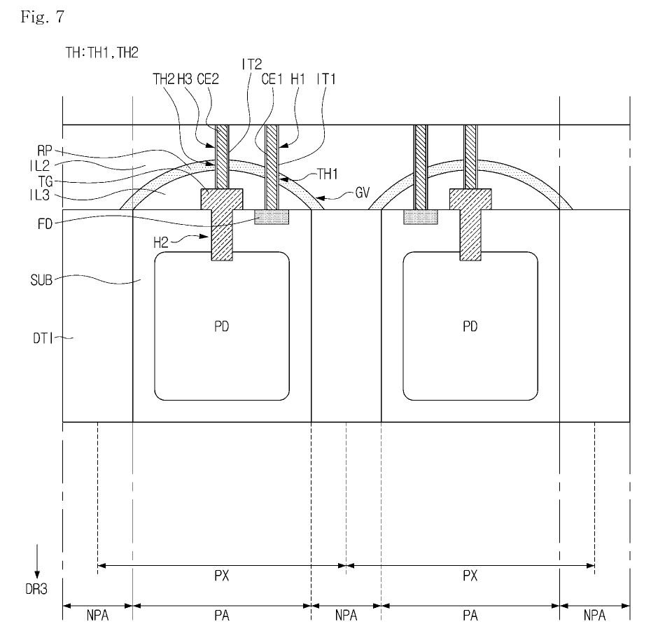

Next, referring to FIG. 7, the first intermediate insulating layer IT1 and the first connecting portion CE1 may be formed in the first groove H1, and the second intermediate insulating layer IT2 and the second connecting portion CE2 may be formed in the third groove H3.

The insulating layer may be formed over the entire area of the second insulating layer IL2.

Subsequently, an etching process may be performed to remove the insulating layer disposed on one side of the second insulating layer IL2 and the insulating layer disposed on the gate electrode TG and the floating diffusion region FD exposed by each of the first groove H1 and the third groove H3.

As a result, the first intermediate insulating layer IT1 disposed on the side of the first groove H1 and the second intermediate insulating layer IT2 disposed on the side of the second groove H2 may be formed.

Next, the first connection portion CE1 may be formed in the first intermediate insulating layer IT1 in the first groove H1, and the second connecting portion CE2 may be formed in the second intermediate insulating layer IT2 in the second groove H2.

In the case of the first connecting portion CE1 and the second connecting portion CE2, a metal layer may be formed on one surface of the second insulating layer IL2, and the metal layer may also be formed inside the first groove H1 and the third groove H3. By etching the metal layer and performing patterning to remove the metal layer disposed on one surface of the second insulating layer IL2, the first connecting portion CE1 and the second connecting portion CE2 may be formed.

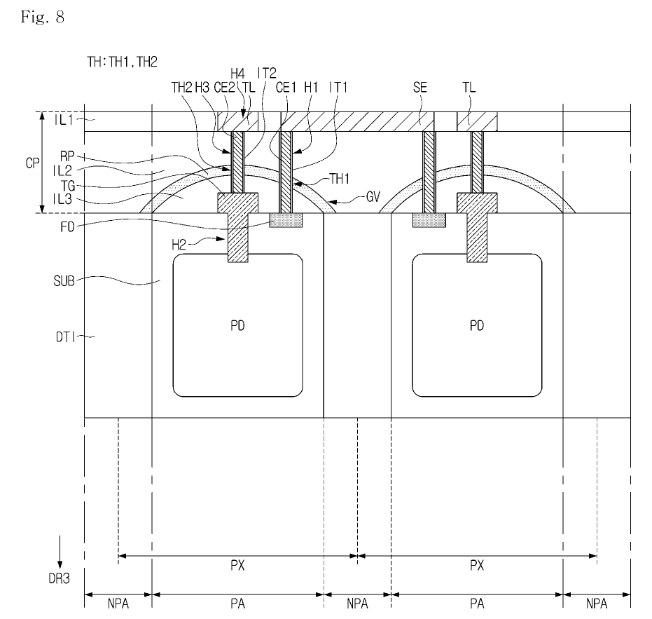

Next, referring to FIG. 8, the first insulating layer IL1 may be formed on the second insulating layer IL2, and the shared electrode SE and the transmission control line TL may be formed within the first insulating layer IL1. The shared electrode SE may contact the first connection portion CE1, and the transmission control line TL may contact the second connecting portion CE2.

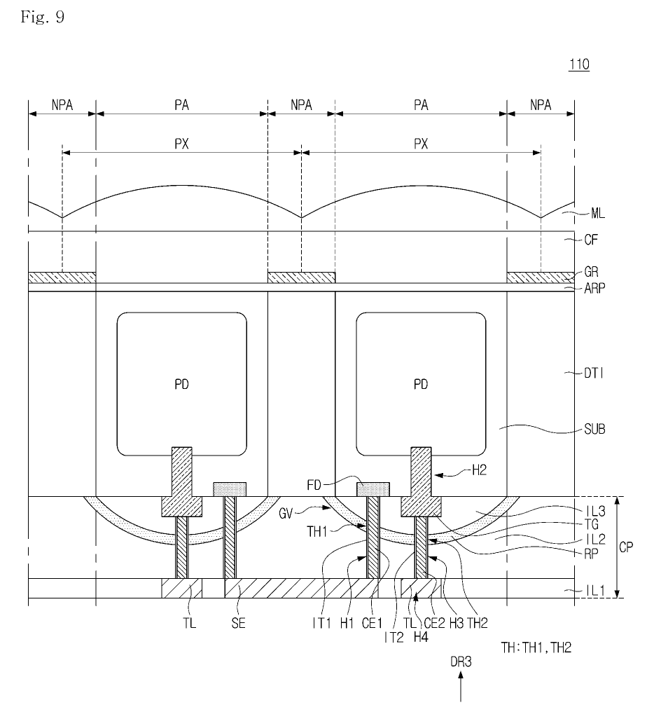

Next, referring to FIG. 9, the anti-reflection layer ARP, the grid portion GR, the color filter CF, and the micro lens ML are sequentially formed on the other side of the substrate portion SUB. Here, the other side of the substrate portion SUB may refer to the upper surface of the substrate portion SUB of FIG. 3.

The grid portion GR may be arranged in the non-pixel area NPA, and the anti-reflection layer ARP, the color filter CF, and the micro lens ML may be arranged across the pixel area PA and the non-pixel area NPA.

Other embodiments of the disclosed technology are described below. For components that are substantially the same as those described with reference to FIGS. 1-9, the same drawing numeral references are given, and overlapping content may be omitted or simplified.

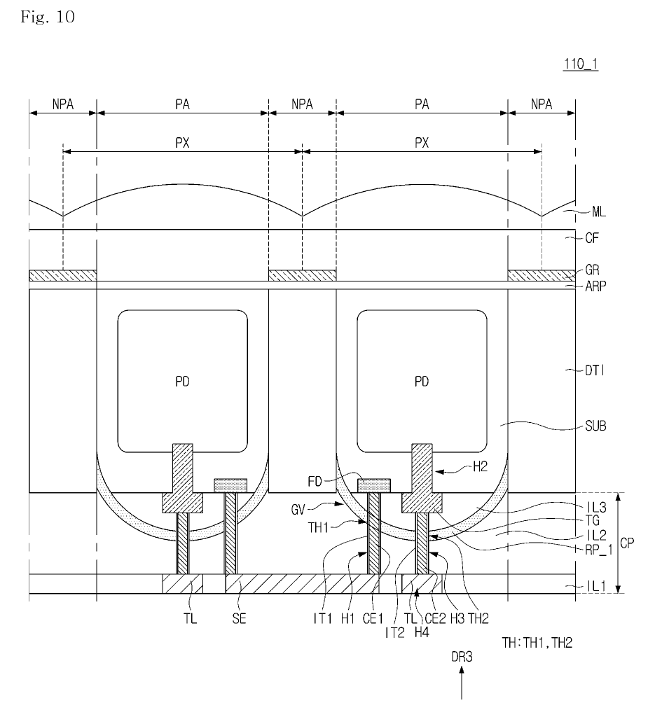

FIG. 10 is a cross-sectional view of an image sensing device according to another embodiment.

Referring to FIG. 10, the image sensing device based on an embodiment includes a pixel array 110_1, and the pixel array 110_1 may include a reflective pattern RP_1.

The reflective pattern RP_1 may be in direct contact with the side surface of the isolation layer DTI. At least a portion of the reflective pattern RP_1 in the pixel area PA may be inserted into the substrate portion SUB. The reflective pattern RP_1 inserted into the substrate portion SUB may cover the entire area of the pixel area PA and may be in contact with the side surface of the isolation layer DTI.

Accordingly, a portion of the second insulating layer IL2 may protrude into the substrate portion SUB. The second insulating layer IL2 inserted into the substrate portion SUB may be in direct contact with the side surface of the isolation layer DTI.

The reflective pattern RP_1 may have the same size as the planar pixel area PA. The third insulating layer IL3 may have a smaller size than the planar pixel area PA.

In this case, as the reflective pattern RP_1 is in direct contact with the isolation layer DTI, the light incident on the inside of the pixel array 110_1 may be suppressed or prevented from leaking, allowing for more efficient light collection and reduced light loss. Furthermore, the detection performance of the image sensing device may be improved, leading to improved signal quality image quality.

When the reflective pattern RP_1 is inserted into the substrate portion SUB and is in contact with the side of the isolation layer DTI, the light incident on the inside of the pixel array 110_1 may be more effectively suppressed or prevented from leaking.

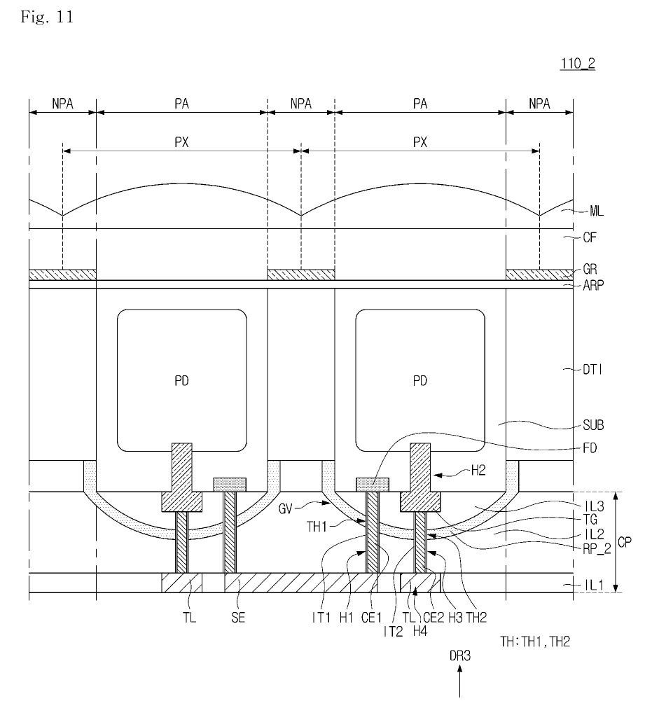

FIG. 11 is a cross-sectional view of an image sensing device based on another embodiment.

Referring to FIG. 11, the image sensing device based on an embodiment may include a pixel array 110_2, and the pixel array 110_2 may include a reflective pattern RP_2 and an isolation layer DTI.

The isolation layer DTI may be formed by recessing an upper portion of the substrate portion SUB in the non-pixel area NPA. The isolation layer DTI does not expose the circuit portion CP, and the circuit portion CP may be covered by the substrate portion SUB across the pixel area PA and the non-pixel area NPA.

The substrate portion SUB may be arranged across the pixel area PA and the non-pixel area NPA. In the non-pixel area NPA, the substrate portion SUB may be arranged between the isolation layer DTI and the circuit portion CP.

The reflective pattern RP_2 may be in direct contact with the lower surface of the isolation layer DTI. In the non-pixel area NPA, at least a portion of the reflective pattern RP_2 may be inserted into the substrate portion SUB. In the non-pixel area NPA, the reflective pattern RP_2 may be arranged between the substrate portion SUB arranged in the non-pixel area SUB and the substrate portion SUB arranged in the pixel area PA. The reflective pattern RP_2 inserted into the substrate portion SUB may be in contact with the lower surface of the isolation layer DTI in the non-pixel area NPA.

Accordingly, even if the isolation layer DTI is formed by recessing a portion of the substrate portion SUB in the thickness direction (third direction DR3), since the reflective pattern RP_2 in the non-pixel area NPA is in direct contact with the lower surface of the isolation layer DTI, any space through which light could leak from the pixel array 110_2 may be eliminated or minimized.

In this case, as the reflective pattern RP_2 is in direct contact with the isolation layer DTI, light leakage from the pixel array 110_2 may be suppressed or prevented, enabling smoother light collection and reducing light loss. Furthermore, the detection performance of the image sensing device may be improved, leading to improved signal quality and image quality.

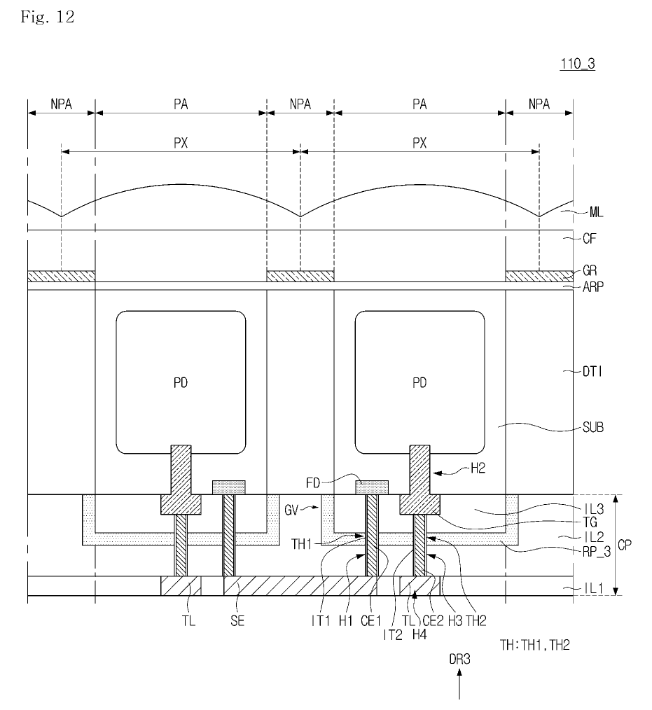

FIG. 12 is a cross-sectional view of an image sensing device based on another embodiment.

Referring to FIG. 12, the image sensing device based on an embodiment includes a pixel array 110_3, and the pixel array 110_3 may include a reflective pattern RP_3. The reflective pattern RP_3 may have a partial square shape in a cross-sectional view.

The reflective groove GV of the second insulating layer IL2 may have a square shape in a cross-sectional view. The third insulating layer IL3 may have a square shape in a cross-sectional view. The cross-sectional shape of the reflective pattern RP_3 may correspond to the cross-sectional shapes of the reflective groove GV and the third insulating layer IL3.

Since the reflective pattern RP_3 is in direct contact with the lower surface of the separating portion DTI, any space through which light could leak from the pixel array 110_3 may be eliminated or minimized.

In this case, as the reflective pattern RP_3 is in direct contact with the isolation layer DTI, light leakage from the pixel array 110_3 may be suppressed or prevented, enabling smoother light collection and reducing light loss. Furthermore, the detection performance of the image sensing device may be improved, leading to improved signal quality and image quality.

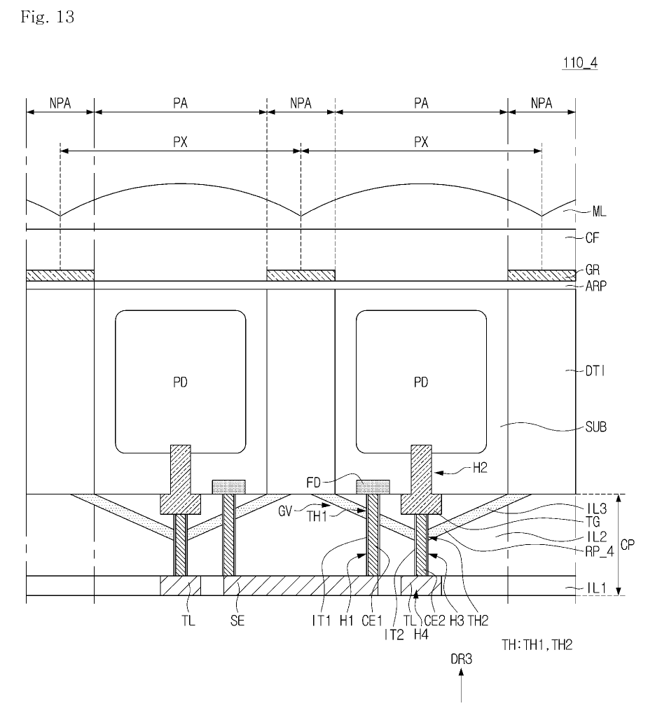

FIG. 13 is a cross-sectional view of an image sensing device based on another embodiment.

Referring to FIG. 13, the image sensing device according to the present embodiment includes a pixel array 110_4, and the pixel array 110_4 may include a reflective pattern RP_4. The reflective pattern RP_4 may have a partial triangular shape in a cross-sectional view.

The reflective groove GV of the second insulating layer IL2 may have a triangular shape in a cross-sectional view. The third insulating layer IL3 may have a triangular shape in a cross-sectional view. The cross-sectional shape of the reflective pattern RP_4 may correspond to the cross-sectional shapes of the reflective groove GV and the third insulating layer IL3.

Since the reflective pattern RP_4 is in direct contact with the lower surface of the separating portion DTI, any space through which light could leak from the pixel array 110_4 may be eliminated or minimized.

In this case, as the reflective pattern RP_4 is in direct contact with the isolation layer DTI, light leakage from the pixel array 110_4 may be suppressed or prevented, enabling smoother light collection and reducing light loss. Furthermore, the detection performance of the image sensing device may be improved, leading to improved signal quality and image quality.

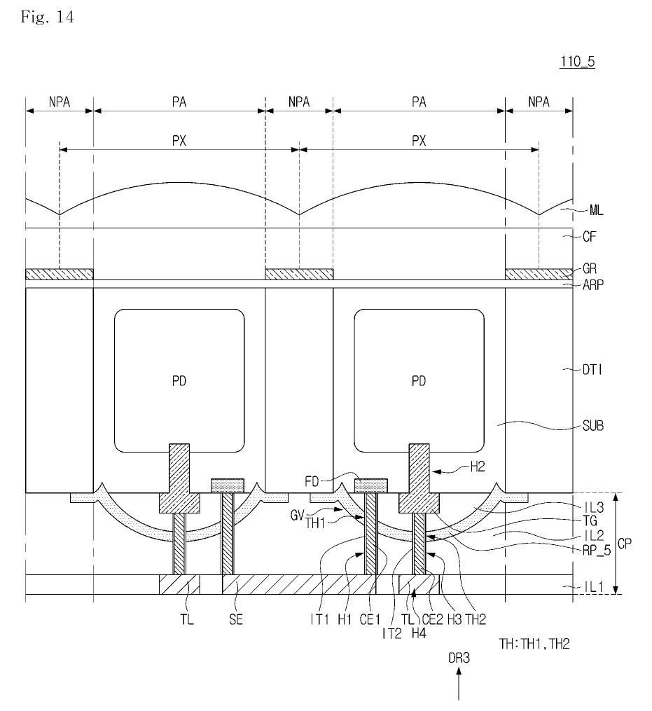

FIG. 14 is a cross-sectional view of an image sensing device based on another embodiment.

Referring to FIG. 14, the image sensing device based on an embodiment includes a pixel array 110_5, and the pixel array 110_5 may include a reflective pattern RP_5. The reflective pattern RP_5 may have a dome shape, and a portion of the reflective pattern RP_5 may protrude such that it is inserted into the substrate portion SUB from the pixel area PA.

The third insulating layer IL3 arranged between the substrate portion SUB and the reflective pattern RP_5 may have a size (area) smaller than the pixel area PA in a planar view.

Since the reflective pattern RP_5 is in direct contact with the lower surface of the isolation layer DTI, any space through which light could leak from the pixel array 110_5 may be eliminated or minimized.

In this case, as the reflective pattern RP_5 is in direct contact with the isolation layer DTI, light leakage from the pixel array 110_5 may be suppressed or prevented, enabling smoother light collection and reducing light loss. Furthermore, the detection performance of the image sensing device may be improved, leading to improved signal quality and image quality.

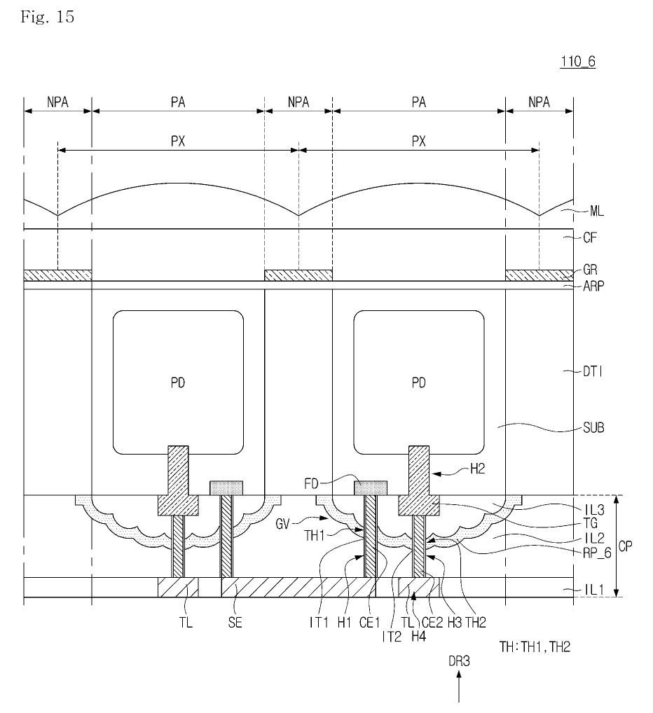

FIG. 15 is a cross-sectional view of an image sensing device based on another embodiment.

Referring to FIG. 15, the image sensing device according to the present embodiment includes a pixel array 110_6, and the pixel array 110_6 may include a reflective pattern RP_6. The reflective pattern RP_6 may have an overall dome shape and may be formed in an embossing shape.

The inner surface of the reflective pattern RP_6 may include a plurality of concave portions that protrude from the inner surface toward the outer surface. Here, the inner surface of the reflective pattern RP_6 may refer to a surface facing the third insulating layer IL3.

Since the reflective pattern RP_6 is in direct contact with the lower surface of the isolation layer DTI, any space through which light could leak from the pixel array 110_6 may be eliminated or minimized.

In this case, as the reflective pattern RP_6 is in direct contact with the separation part DTI, light leakage from the pixel array 110_6 may be suppressed or prevented, enabling smoother light collection and reducing light loss. Furthermore, the detection performance of the image sensing device may be improved. As a result, the quality of the signal can be improved, and the image quality can be improved.

Only a few implementations and examples of the disclosed technology are described and other implementations, enhancements and variations can be made based on what is described and illustrated in this patent document.

What is claimed is:

1. An image sensing device comprising:
a plurality of insulating layers comprising:
a first insulating layer;
a second insulating layer disposed over the first insulating layer; and
a third insulating layer disposed over the second insulating layer;
a substrate portion disposed over the third insulating layer;
a photodetector disposed within the substrate portion;
a reflective pattern disposed between the second insulating layer and the third insulating layer;
an isolation layer disposed between the substrate portion and an adjacent substrate portion,
wherein the reflective pattern is in direct contact with the isolation layer.

2. The image sensing device of claim 1, wherein:
the substrate portion and the photodetector are disposed in a pixel area;
the isolation layer is disposed in a non-pixel area disposed adjacent to the pixel area; and
the reflective pattern encloses the pixel area.

3. The image sensing device of claim 2, wherein at least one end of the reflective pattern is in direct contact with a lower surface of the isolation layer opposite to the second insulating layer.

4. The image sensing device of claim 1, wherein at least one end of the reflective pattern is in direct contact with a lateral surface of the isolation layer.

5. The image sensing device of claim 4, wherein a portion of the reflective pattern is inserted into the substrate portion, and the portion of the reflective pattern inserted into the substrate portion includes the at least one end of the reflective pattern in direct contact with the lateral surface of the isolation layer.

6. The image sensing device of claim 1, further comprising:
a gate electrode disposed above the reflective pattern and in contact with the photodetector;
a transmission control line disposed below the reflective pattern; and
a connecting portion disposed between the gate electrode and the transmission control line,
wherein the reflective pattern comprises at least one through hole, and
the connecting portion extends through the through hole.

7. The image sensing device of claim 6, further comprising:
an intermediate insulating layer disposed between the connecting portion and the reflective pattern.

8. The image sensing device of claim 1, wherein:
the photodetector and the reflective pattern are included in one of a plurality of pixels disposed over the first insulating layer.

9. The image sensing device of claim 8, wherein the reflective patterns disposed in the plurality of pixels are physically separated from each other.

10. The image sensing device of claim 1, wherein the third insulating layer is disposed between the substrate portion and the reflective pattern.

11. The image sensing device of claim 10, wherein the third insulating layer is surrounded by the substrate portion and the reflective pattern.

12. The image sensing device of claim 1, wherein the reflective pattern is disposed between the second insulating layer and the third insulating layer, and
the second insulating layer and the third insulating layer are physically separated from each other.

13. The image sensing device of claim 12, wherein the isolation layer is disposed to pass through the substrate portion in a thickness direction, and
a planar dimension of the substrate portion is identical to a planar dimension of the third insulating layer.

14. An image sensing device comprising:
a substrate portion;
a photodetector disposed within the substrate portion;
an isolation layer disposed adjacent to the substrate portion; and
a reflective pattern disposed below the substrate portion,
wherein the substrate portion is disposed in a pixel area, and the isolation layer is disposed in a non-pixel area disposed adjacent to the pixel area,
wherein the reflective pattern encloses the pixel area.

15. The image sensing device of claim 14, wherein at least one end of the reflective pattern is in direct contact with the isolation layer.

16. The image sensing device of claim 14, further comprising:
a plurality of insulating layers including a third insulating layer disposed over one surface of the reflective pattern, and a second insulating layer disposed over another surface of the reflective pattern,
wherein the third insulating layer and the second insulating layer are physically separated from each other.

17. The image sensing device of claim 16, wherein the third insulating layer is disposed between the substrate portion and the reflective pattern, and
the third insulating layer is surrounded by the substrate portion and the reflective pattern.

18. The image sensing device of claim 14, further comprising:
a gate electrode disposed above the reflective pattern and in contact with the photodetector;
a transmission control line disposed below the reflective pattern; and
a connecting portion disposed between the gate electrode and the transmission control line,
wherein the reflective pattern comprises at least one through hole, and
the connecting portion extends through the through hole.

19. The image sensing device of claim 18, further comprising:
an intermediate insulating layer disposed between the connecting portion and the reflective pattern.

20. A method of manufacturing an image sensing device comprising:
forming an isolation layer by recessing a substrate portion including a photodetector in a thickness direction of the substrate portion;
patterning a third insulating layer disposed over the substrate portion;
patterning a reflective pattern disposed over the third insulating layer; and
patterning a second insulating layer disposed over the reflective pattern,
wherein the reflective pattern is in direct contact with an isolation layer disposed between the substrate portion and an adjacent substrate portion.
